(19) United States
(12) Patent Application Publication
(10) Pub. No.: US 2013/0127445 A1
(43) Pub. Date: May 23, 2013

(54) TEST FIXTURE WITH LOAD

(71) Applicants: LEI YUAN, Shenzhen City (CN); XU XIA, Shenzhen City (CN)

(72) Inventors: LEI YUAN, Shenzhen City (CN); XU XIA, Shenzhen City (CN)

(73) Assignees: HON HAI PRECISION INDUSTRY CO., LTD., Tu-Cheng (TW); HONG FU JIN PRECISION INDUSTRY (Shenzhen) CO., LTD, Shenzhen City (CN)

(21) Appl. No.: 13/332,386

(22) Filed: Dec. 21, 2011

(30) Foreign Application Priority Data
Nov. 18, 2011 (CN) 201110367871.3

(51) Int. Cl. G01R 1/20

(52) U.S. Cl. 324/126

(57) ABSTRACT

A test fixture with a load for measuring an output voltage of a connecting port with a voltmeter at full load is illustrated. The test fixture includes a main body, a plug comprising a first pin and a second pin for respectively contacting the two lines of the connecting port. A first contact connected to the first pin through a first wire, a second contact connected to the second pin through a second wire, and a load connected between the first wire and the second wire. The plug is connected to one end of the main body and capable of being inserted into the connecting port.

### BACKGROUND

1. Technical Field

The present disclosure relates to a test fixture, and particularly, to a test fixture with a load.

2. Description of Related Art

Connecting ports (e.g., USB ports) are widely used in electronic devices, such as in portable computers, mobile phones, and tablet computers, for example. The connecting port can be used to transfer data. During manufacturing, an output voltage of connecting port needs to be measured at full load, to determine whether the connecting port at full load can provide sufficient voltage. Thus, it is necessary to provide a test fixture that can cooperate with a voltmeter to measure the output voltage of connecting port at full load.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a test fixture according to an exemplary embodiment.

FIG. 2 is a circuit connection diagram of the test fixture of FIG. 1 and a connecting port.

### DETAILED DESCRIPTION

Embodiments of the present disclosure are now described in detail, with reference to the accompanying drawings.

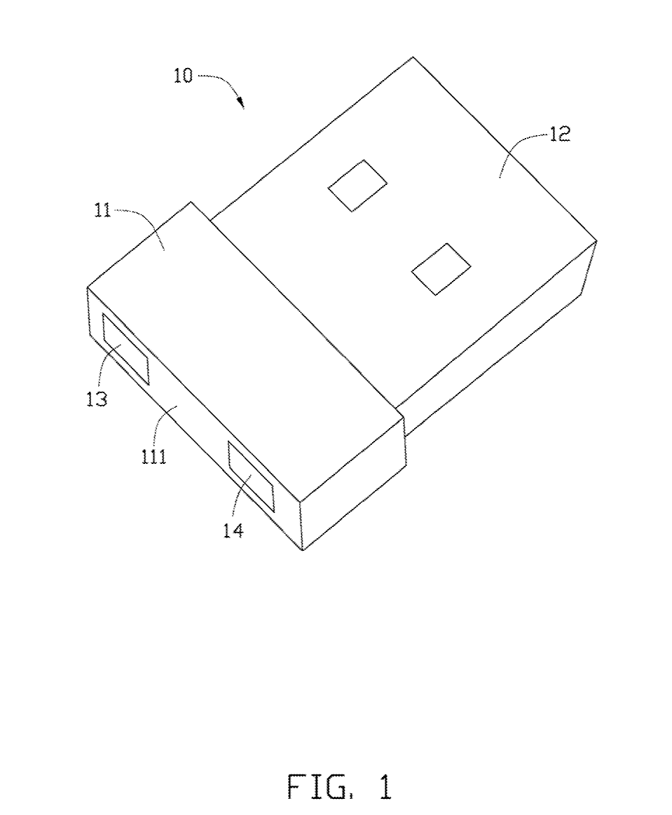

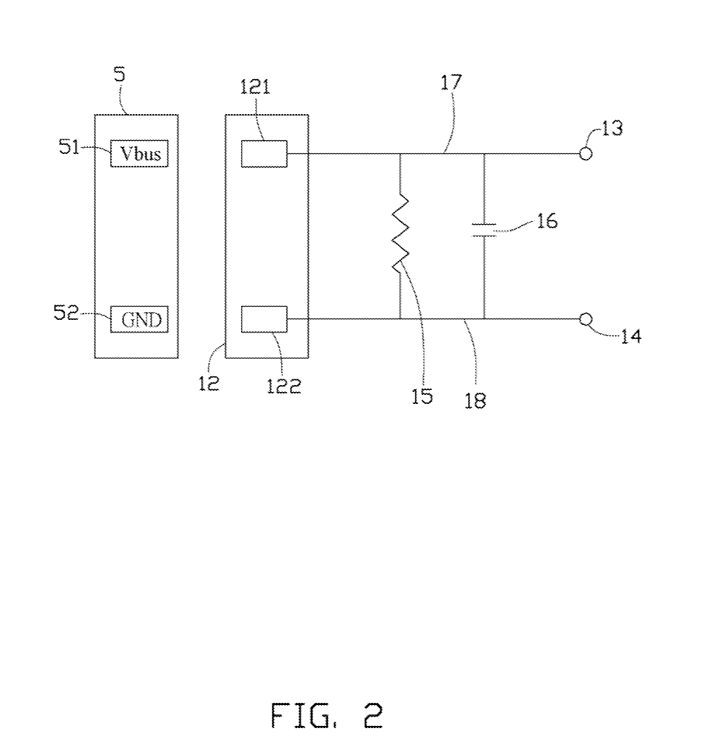

Referring to FIGS. 1-2, a test fixture 10 according to an exemplary embodiment is illustrated. The test fixture 10 includes a main body 11 and a plug 12 connected to one end of the main body 11. The plug 12 can be inserted into a connecting port 5 of an electronic device (not shown).

The connecting port 5 includes a Vbus line 51 and a GND line 52 providing an output voltage therebetween. In the embodiment, the connecting port 5 is a universal serial bus (USB) port, and the output voltage between the Vbus line and the GND line is nominally about 5 volts.

The main body 11 includes a side surface 111 opposite the plug 12. A first contact 13 and a second contact 14 are formed on the side surface 111. In the embodiment, the first contact 13 and the second contact 14 are made of copper. The plug 12 includes a first pin 121 and a second pin 122 for electrically connecting with corresponding lines of the connector port 5. The first contact 13 is connected to the first pin 121 through a first wire 17, and the second contact 13 is connected to the second pin 122 through a second wire 18. The test fixture 10 includes a load 15 connected between the first wire 17 and the second wire 18. In the embodiment, the load 15 is a resistor with a resistance value of 10 ohms.

The test fixture 10 further includes a capacitor 16 connected between the first wire 17 and the second wire 18 in parallel with the load 15. The load 15 filters voltage clutter between the first wire 17 and the second wire 18. The capacitance value of the capacitor 16 is between about 4.7-5.3 microfarads. In the embodiment, the load 15, the capacitor 16, the first wire 17, and the second wire 18 can be arranged on a circuit board retained in the main body 11.

After the plug 12 is inserted into the connecting port 5, the first pin 121 and the second pin 122 respectively contact the Vbus line 51 and the GND line 52. The voltage between the contacts 13 and 14, which substantially equals to the actual voltage between the Vbus line 51 and the GND line 52 at full load, can be measured by a voltmeter.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A test fixture with a load for use with a voltmeter for measuring an output voltage between two lines in a connecting port at full load, the test fixture comprising:
a main body;
a plug connected to one end of the main body and capable of being inserted into the connecting port, the plug comprising a first pin and a second pin that respectively contact the two lines when the plug is inserted into the connecting port; and
a first contact connected to the first pin through a first wire;
a second contact connected to the second pin through a second wire; and
a load connected between the first wire and the second wire.

2. The test fixture as described in claim 1, wherein the main body comprises a side surface opposite the plug, and the first contact and the second contact are formed on the side surface.

3. The test fixture as described in claim 1, further comprising a capacitor connected between the first wire and the second wire in parallel with the load.

4. The test fixture as described in claim 3, wherein the connecting port is a USB port and the capacitance value of the capacitor is between about 4.7-5.3 microfarads.

5. The test fixture as described in claim 1, wherein the connecting port is a USB port, and the load is a resistor.

6. The test fixture as described in claim 5, wherein the resistance value of the resistor is about 10 ohms.

7. The test fixture as described in claim 1, wherein the first wire, the second wire, and the load are arranged on a circuit board retained within the main body.

8. The test fixture as described in claim 1, wherein the first contact and the second contact are made of cooper.
